(19) United States
(12) Patent Application Publication
(10) Pub. No.: US 2026/0040973 A1
(43) Pub. Date: Feb. 5, 2026

(54) PACKAGE SUBSTRATE WITH CORE HAVING METALLIZATION LAYERS TO FACILITATE SIGNAL ROUTING WITHIN THE CORE, AND RELATED FABRICATION METHODS AND INTEGRATED CIRCUIT (IC) PACKAGES

(71) Applicant: QUALCOMM Incorporated, San Diego, CA (US)

(72) Inventors: Hong Bok We, San Diego, CA (US); Joan Rey Villarba Buot, Escondido, CA (US); Seongryul Choi, Seongnam (KR); Kuiwon Kang, San Diego, CA (US)

(21) Appl. No.: 18/791,595

(22) Filed: Aug. 1, 2024

(51) Int. Cl. H01L 23/498; H01L 21/48; H01L 23/00; H01L 25/10

(52) U.S. Cl. CPC H01L 23/49838; H01L 21/4857; H01L 23/49822; H01L 23/49816; H01L 24/16; H01L 25/105; H01L 2224/16227; H01L 2225/1041

(57) ABSTRACT

Package substrate with a core having metallization layers to facilitate signal routing within the core, and related fabrication methods and integrated circuit (IC) packages. The core includes multiple core metallization layers that can be formed separately and coupled to each other to provide signal routing within the core. Metal interconnects in the multiple core metallization layers are coupled to each other through coupling of the core metallization layers to each other in the core to provide signal routing paths through the core. Including separate core metallization layers in the core provides flexibility in patterning location of the metal interconnects therein for routing flexibility within the core. This is opposed to only including singular body, vertical interconnects extending through the entire height of the core. Metal interconnects can also be patterned to extend laterally within a respective core metallization layer to provide lateral signal routing paths within a core metallization layer.

### TECHNICAL FIELD

The field of the disclosure relates to integrated circuit (IC) packages, and more particularly to design and manufacture of package substrates that support signal routing to a semiconductor die(s) in the IC package.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a substrate as a routing substrate (e.g., a package substrate) to provide physical support and an electrical interface to the die(s). The die(s) is electrically interfaced to metal interconnects (e.g., metal traces) exposed in an upper layer of the substrate as part of signal routing paths. The substrate also includes one or more metallization layers that include metal interconnects (e.g., metal traces, metal lines) with vertical interconnect accesses (vias) coupling the metal interconnects together between adjacent metallization layers to provide electrical interfaces between the dies. If the substrate is a package substrate, the substrate also includes a lower, outer metallization layer that includes metal interconnects coupled to external metal interconnects (e.g., ball grid array (BGA) interconnects) to provide an external interface between the dies in the IC package. The external metal interconnects can also be coupled (e.g., soldered) to traces in a printed circuit board (PCB) to attach the package to the PCB and interface its die(s) with the circuitry of the PCB.

A package substrate can include an internal core disposed between metallization layers, wherein the core can be made from a hardened laminate layer (e.g., a pre-impregnated (PPG) material) to provide increased firmness and support for less susceptibility to warpage. To provide signal routing paths between the metallization layers on each side of the core, vertical interconnects are formed in the core. For example, this signal routing can include power signals distributed within the package substrate. The vertical interconnects extend vertically through the core and are exposed to adjacent metallization layers for forming connections between the core and metal interconnects in the metallization layers adjacent to the core for signal routing. The vertical interconnects are formed by first forming inner via holes (IVHs) through the core, and then filling the IVHs with a metal material (e.g., copper) to form vertical interconnects (e.g., metal pillars). Metal pads (i.e., IVH metal pads) are formed in contact with the exposed ends of the vertical interconnects to facilitate providing interconnections between the vertical interconnects and metal interconnects in adjacent metallization layers. The location of the IVHs in the core governs the placement of the IVH pads formed in contact with the vertical interconnects formed in the IVHs. Further, a process tolerance is provided for registering the IVH pads in contact with the vertical interconnects to ensure that a sufficient contact is provided between the IVH pads and the vertical interconnects. Thus, the IVHs in the core can limit routing flexibility in the package substrate, which may make it more difficult to optimize reduction of the size of the package substrate to reduce the size of its IC package.

It may also be desired to provide a thicker core in a package substrate for larger die packages to provide sufficient support and to reduce or avoid warpage. However, a thicker core increases the height of the IVHs that then must be filled with metal material to form the vertical interconnects through the core. Process limitations may limit the amount of metal material that can be filled in a taller IVH (e.g., taller than 300 micrometers (μm)) without risk of concave dimples on the exposed ends of the vertical interconnects. Dimples reduce connectivity area between the vertical interconnects and metal pads and thus increase resistance of signals routed through such vertical interconnects. A dielectric material “plug” could be disposed in the IVH and then a metal material formed around the dielectric material to reduce the amount of fill metal material disposed in the IVH to avoid dimples. However, this also has the effect of reducing the metal volume of the vertical interconnects which also reduces the resistance of such interconnects. The IVHs could also be overfilled with metal material thus forming a portion of the IVH pads to avoid dimples. However, this would then increase the thickness of the IVH pads in metallization layers adjacent to the core thus further increasing the height of the package substrate and its IC package in an undesired manner.

### SUMMARY OF THE DISCLOSURE

Aspects disclosed herein include a package substrate with a core having metallization layers to facilitate signal routing within the core. Related fabrication methods and integrated circuit (IC) packages that include package substrates with a core having metallization layers to facilitate signal routing within the core are also disclosed. The package substrate is a substrate that includes outer metallization layers that include patterned metal interconnects (e.g., metal lines, metal traces) coupled to vias extending in a second, vertical direction orthogonal to a first direction(s) to provide lateral signal routing paths in the first, lateral direction. To provide additional support and rigidity to the package substrate to reduce or avoid warpage, a core (also referred to as a “core layer”) is disposed between metallization layers in the second, vertical direction orthogonal to the first direction. The core is a layer made from a hardened, dielectric material (e.g., a pre-impregnated (PPG) material) to provide increased stiffness and rigidity for the package substrate and its IC package, as opposed to using a less rigid dielectric material (e.g., epoxy-resin based materials and films (e.g., Ajinomoto Build-up Film (ABF)) that may support finer patterning capability for forming finer pitch metal interconnects therein with reduced line-spacing (L/S) for increased signal routing density.

In exemplary aspects, to provide for the core in the package substrate to also have signal routing capability as opposed to only including vertical interconnects that extend through the entire height of the core in the second, vertical direction to transport signals between metallization layers on each side of the core, the core includes multiple core metallization layers. In an example, the core includes a first core metallization layer having a first core insulating layer of a rigid dielectric material and patterned with first metal interconnects coupled to first vias similar to the outer metallization layers in the package substrate. The core also includes a second core metallization layer that has a second core insulating layer also of a rigid dielectric material and patterned with second metal interconnects coupled to second vias also similar to the metallization layers in the package substrate. First metal interconnects exposed from the first core insulating layer of the first core metallization layer are coupled to respective second metal interconnects exposed from the second core insulating layer of the second core metallization layer to provide signal routing capability in the core of the package substrate. For example, because the first and second metal interconnects that are coupled together are formed separately in their respective first and second core metallization layers, their respective coupled first and second metal interconnects do not have to be aligned in the second, vertical direction to support signal routing paths within the core. This provides additional flexibility in patterning the location of these metal interconnects within the core for routing flexibility within the core. This also allows vias in the respective first and second core metallization layers that are coupled to respective first and second metallization layers to extend signal routing through the core to the outer metallization layers of the package substrate to also not have to be aligned in second, vertical direction to support signal routing in the first, lateral direction(s) within the core. This is opposed to only including vertical interconnects that extend through the entire height of the core. Also, providing the core with multiple core metallization layers allows the metal interconnects therein to also be patterned, if desired, to extend in the first, lateral direction(s) to provide lateral signal routing paths between multiple metal interconnects within the same core insulating layer in the core. These exemplary features provide signal routing capability within the core of the package substrate. Providing signal routing capability in the core can increase the routing density and capability in the package substrate without the need to necessarily provide additional, non-core metallization layers in the package substrate.

In another exemplary aspect, providing the core of the package substrate with multiple core metallization layers allows the metal interconnects in each core metallization layer of the core metallization layers to be formed separately in openings therein that do not have to extend the full height of the core in the second, vertical direction. This allows the metal interconnects to be formed in the core metallization layers from patterned openings that only have to extend partially into their respective core insulating layer, thus reducing the aspect ratio of these openings as compared to openings that would be formed through the entire height of a core in the second, vertical direction. In this manner, the metal interconnects in the core insulating layers as well as their interconnecting vias can be formed with a reduced L/S ratio with a tighter pitch to increase signal routing density in the core. Reduced height openings in core insulating layers in which metal interconnects are formed can also allow fabrication methods to be used to form the openings (e.g., drilling) and form the metal interconnects (e.g., through metal plating) that further minimize the aspect ratio of such openings. Also, providing the core of the package substrate with multiple core metallization layers can allow the overall core to be provided with a larger height in the second, vertical direction if desired, such as to support larger IC packages, but without the risk of dimples that may result from a metal fill process in an inter via hole (IVH) extending through the entire height of the core.

In other exemplary aspects, the core metallization layers of the core can be semi-additive process (SAP) embedded trace substrate (ETS) metallization layers that are formed from a SAP process wherein their metal interconnects are formed by a metal plating process on a core insulating layer that is then patterned to form the metal interconnects. In another exemplary aspect, the core metallization layers of the core can be ETS metallization layers wherein their ETS metal interconnects are formed by embedding a metal material in patterned openings formed in a respective core insulating layer. A benefit of the core including core ETS metallization layers is that ETS metallization layers can support a reduced L/S ratio to support finer pitched ETS metal interconnects for increased routing density and capability in the core of the package substrate. Also, in the example of the core including ETS metallization layers, because the ETS metal interconnects in the ETS metallization layers are embedded within a core insulating layer with their upper surfaces generally planar and exposed from the outer surface of their respective core insulating layer, the exposed ETS metal interconnects from their ETS metallization layers can be directly coupled to each other to form the core and to provide signal routing paths in the core without needing raised metal pads that would otherwise increase the height of the core in the second, vertical direction.

In this regard, in one exemplary aspect, a substrate is disclosed. The substrate includes a first metallization layer extending in a first direction. The substrate also includes a second metallization layer extending in the first direction. The substrate also includes a core between the first metallization layer and the second metallization layer in a second direction orthogonal to the first direction. The core includes a first core metallization layer. The first core metallization layer includes a first core insulating layer and a plurality of first metal interconnects. The core also includes a second core metallization layer adjacent to the first core metallization layer in the second direction. The second core metallization layer includes a second core insulating layer and a plurality of second metal interconnects. A first one or more first metal interconnects of the plurality of first metal interconnects in the first core metallization layer are each coupled to a second metal interconnect of the plurality of second metal interconnects in the second core metallization layer.

In another exemplary aspect, a method of fabricating a substrate for an IC package is disclosed. The method includes forming a core. Forming the core includes forming a first core metallization layer extending in a first direction. Forming the first core metallization layer includes forming a first core insulating layer and forming a plurality of first metal interconnects. Forming the core also includes forming a second core metallization layer extending in the first direction. Forming the second core metallization layer includes forming a second core insulating layer and forming a plurality of second metal interconnects. Forming the core also includes coupling the second core metallization layer to the first core metallization layer in a second direction orthogonal to the first direction coupling each of a first one or more first metal interconnects of the plurality of first metal interconnects in the first core metallization layer to a second metal interconnect of the plurality of second metal interconnects in the second core metallization layer. The method also includes forming a first metallization layer adjacent to the first core metallization layer in the second direction. The method also includes forming a second metallization layer adjacent to the second core metallization layer in the second direction.

### BRIEF DESCRIPTION OF THE FIGURES

FIG. 1 is a side view of an exemplary integrated circuit (IC) package that includes a first die package with a first die coupled to a package substrate and a second die package with a second die coupled to the first die package through an interposer package substrate, wherein any of the package substrates can include a core having core metallization layers to facilitate signal routing within the core to allow increased signal routing density in the IC package;

FIGS. 2A and 2B are a side view and close-up side view, respectively, of an exemplary substrate that includes a core surrounded by outer metallization layers in a second, vertical direction, wherein the core has multiple core metallization layers with metal interconnects in the respective core metallization layers coupled to each other to facilitate signal routing within the core, and wherein the package substrate can be included in any of the die packages in the IC package in FIG. 1;

FIG. 3 is a side view of another exemplary package substrate that includes the core in the substrate in FIGS. 2A and 2B, but is surrounded by multiple metallization layers on each side of the core in the second, vertical direction that were formed by a semi-additive process (SAP), and wherein the package substrate can be included in any of the die packages in the IC package in FIG. 1;

FIG. 4 is a flowchart illustrating an exemplary fabrication process of fabricating a substrate that includes a core surrounded by outer metallization layers in a second, vertical direction, wherein the core has multiple core metallization layers with metal interconnects in the respective core metallization layers coupled to each other to facilitate signal routing within the core, including, but not limited to, the substrates in FIGS. 1-3;

FIGS. 5A-5E is a flowchart illustrating another exemplary process of fabricating a package substrate that includes a core surrounded by outer metallization layers in a second, vertical direction, wherein the core has multiple core embedded trace substrate (ETS) metallization layers with ETS metal interconnects in the respective core ETS metallization layers coupled to each other to facilitate signal routing within the core, including, but not limited to, the package substrates in FIGS. 1-3;

FIG. 6A-6O are exemplary fabrication stages during fabrication of the package substrate according to the exemplary fabrication process in FIGS. 6A-6O;

FIG. 7 is a block diagram of an exemplary wireless communications device that includes one or more IC packages that includes an package substrate that includes a core surrounded by outer metallization layers in a second, vertical direction, wherein the core has multiple core ETS metallization layers with ETS metal interconnects in the respective core ETS metallization layers coupled to each other to facilitate signal routing within the core, including, but not limited to, the package substrates in FIGS. 1-3 and 6O, and that can be fabricated according to a fabrication process, including, but not limited to, the exemplary fabrication processes in FIGS. 4-5E; and

FIG. 8 is a block diagram of an exemplary electronic device in the form of a processor-based system that includes one or more IC packages that includes an package substrate that includes a core surrounded by outer metallization layers in a second, vertical direction, wherein the core has multiple core ETS metallization layers with ETS metal interconnects in the respective core ETS metallization layers coupled to each other to facilitate signal routing within the core, including, but not limited to, the package substrates in FIGS. 1-3 and 6O, and that can be fabricated according to a fabrication process, including, but not limited to, the exemplary fabrication processes in FIGS. 4-5E.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include a package substrate with a core having metallization layers to facilitate signal routing within the core. Related fabrication methods and integrated circuit (IC) packages that include package substrates with a core having metallization layers to facilitate signal routing within the core are also disclosed. The package substrate is a substrate that includes outer metallization layers that include patterned metal interconnects (e.g., metal lines, metal traces) coupled to vias extending in a second, vertical direction orthogonal to the first direction(s) to provide signal routing paths within the core. To provide additional support and rigidity to the package substrate to reduce or avoid warpage, a core (also referred to as a “core layer”) is disposed between metallization layers in the second, vertical direction orthogonal to the first direction. The core is a layer made from a hardened, dielectric material (e.g., a pre-impregnated (PPG) material) to provide increased stiffness and rigidity for the package substrate and its IC package, as opposed to use of a less rigid dielectric material (e.g. epoxy-resin based materials and films (e.g. Ajinomoto Build-up Film (ABF)) that may support finer patterning capability for forming finer pitch metal interconnects therein with reduced line-spacing (L/S) for increased signal routing density.

In exemplary aspects, to provide for the core in the package substrate to also have signal routing capability as opposed to only including vertical interconnects that extend through the entire height of the core in the second, vertical direction to transport signals between metallization layers on each side of the core, the core includes multiple core metallization layers. In an example, the core includes a first core metallization layer having a first core insulating layer of a rigid dielectric material and patterned with first metal interconnects coupled to first vias similar to the outer metallization layers in the package substrate. The core also includes a second core metallization layer that has a second core insulating layer also of a rigid dielectric material and patterned with second metal interconnects coupled to second vias also similar to the metallization layers in the package substrate. First metal interconnects exposed from the first core insulating layer of the first core metallization layer are coupled to respective second metal interconnects exposed from the second core insulating layer of the second core metallization layer to provide signal routing capability in the core of the package substrate. For example, because the first and second metal interconnects that are coupled together are formed separately in their respective first and second core metallization layers, their respective coupled first and second metal interconnects do not have to be aligned in the second, vertical direction to support lateral signal routing in the first, lateral direction(s) within the core. This provides additional flexibility in patterning the location of these metal interconnects within the core for routing flexibility within the core. This also allows vias in the respective first and second core metallization layers that are coupled to respective first and second metallization layers to extending signal routing through the core to the outer metallization layers of the package substrate also do not have to be aligned in second, vertical direction to support lateral signal routing in the first, lateral direction(s) within the core. This is opposed to only including vertical interconnects that extend through the entire height of entire in the core. Also, providing the core with multiple core metallization layers allows the metal interconnects therein to also be patterned, if desired, to extend in the first, lateral direction(s) to provide lateral signal routing paths between multiple metal interconnects within the same core insulating layer in the core. These exemplary features provide signal routing capability within the core of the package substrate. Providing signal routing capability in the core can increase the routing density and capability in the package substrate without the need to necessarily provide additional, non-core metallization layers in the package substrate.

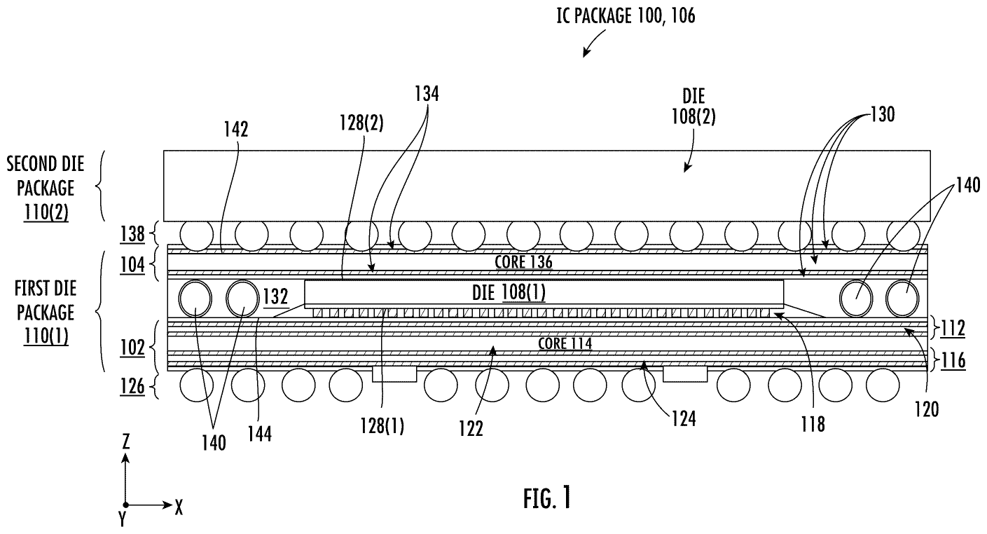

In this regard, FIG. 1 is a side views of an exemplary integrated circuit (IC) package 100 that includes package substrates 102, 104 that as discussed in more detail below, can include a core having core metallization layers to facilitate signal routing in within the core. A package substrate is a substrate that is intended to be included in an IC package to provide support for other electronic components, such as a die, and to provide signal routing paths to such electronic components. Before discussing exemplary details of a package substrate that includes a core having core metallization layers to facilitate signal routing in within the core, including the package substrates 102, 104 in FIG. 1, exemplary details of the IC package 100 are first described.

As shown in FIG. 1, in this example, the IC package 100 is a stacked-die IC package 106 that includes multiple dies 108(1), 108(2) that are included in respective first and second die packages 110(1), 110(2) that are stacked on top of each other in a vertical direction (Z-axis direction). The first die package 110(1) of the IC package 100 includes the first die 108(1) coupled to the package substrate 102. In this example, the package substrate 102 includes first, upper metallization layers 112 disposed on a core substrate 114, also referred to herein as a “core” 114, each of which extends in a first, horizontal (lateral) direction(s) (X-axis and/or Y-axis directions) orthogonal to the second, vertical direction (Z-axis direction). The core 114 is disposed on second, bottom metallization layers 116. The core 114 is provided in the package substrate 102 and disposed between the metallization layers 112, 116 in the second, vertical direction (Z-axis direction) in this example to provide additional support and rigidity to the package substrate 102 to reduce or avoid warpage. For example, the core 114 can be a layer(s) made from a hardened, dielectric material (e.g., a pre-impregnated (PPG) material) to provide increased stiffness and rigidity for the package substrate 102 and thus, in turn, the IC package 100, as opposed to using a less rigid dielectric material (e.g., epoxy-resin based materials and films (e.g., Ajinomoto Build-up Film (ABF)) that may be used in the metallization layers 112, 116. A less rigid dielectric material used in the metallization layers 112, 116 may support finer patterning capability for forming finer pitch metal interconnects therein with a reduced line-spacing (L/S) ratio.

With continuing reference to FIG. 1, the first, upper metallization layers 112 provide an electrical interface for signal routing to the first die 108(1). The first die 108(1) is coupled to die interconnects 118 (e.g., raised metal bumps) that are electrically coupled to metal interconnects 120 in the first, upper metallization layers 112. The metal interconnects 120 in the first, upper metallization layers 112 are coupled to metal interconnects 122 in the core 114, which are coupled to metal interconnects 124 in the second, bottom metallization layers 116. As will be discussed in more detail below, the metal interconnects 122 in the core 114 are not solely vertical interconnects that extend through the entire core 114 as a monolithic component, but are comprised of multiple metal interconnects 122 in multiple core metallization layers that can be laterally offset from each other in the first, horizontal direction(s) (X-axis and/or Y-axis directions) to provide signal routing paths within the core 114. In this manner, the package substrate 102 provides interconnections between its first and second metallization layers 112, 116, and the core 114 to provide signal routing to the first die 108(1).

With continuing reference to FIG. 1, external interconnects 126 (e.g., ball grid array (BGA) interconnects) are coupled to the metal interconnects 124 in the second, bottom metallization layers 116 to provide interconnections through the package substrate 102 to the first die 108(1) through the die interconnects 118. In this example, a first, active side 128(1) of the first die 108(1) is adjacent to and coupled to the package substrate 102, and more specifically the first, upper metallization layers 112 of the package substrate 102.

Also in this example IC package 100 in FIG. 1, an additional optional second die package 110(2) is provided and coupled to the first die package 110(1) to support multiple dies. For example, the first die 108(1) in the first die package 110(1) may include an application processor, and the second die 108(2) may be a memory die, such as a dynamic random access memory (DRAM) die that provides memory support for the application processor. In this regard, in this example, the first die package 110(1) also includes an interposer substrate 104 as another package substrate 104 that is disposed on a package mold 132 encasing the first die 108(1), adjacent to a second, inactive side 128(2) of the first die 108(1). The interposer substrate 104 also includes one or more metallization layers 134 that are disposed on each side of a core 136 similar to the package substrate 102 in the first die package 110(1). The metallization layers 134 and core 136 each include metal interconnects 130 to provide interconnections to the second die 108(2) in the second die package 110(2). The second die package 110(2) is physically and electrically coupled to the first die package 110(1) by being coupled through external interconnects 138 (e.g., solder bumps, BGA interconnects) to the interposer substrate 104. The external interconnects 138 are coupled to the metal interconnects 139 in the interposer substrate 104.

To provide interconnections to route signals from the second die 108(2) through the external interconnects 138 and the interposer substrate 104 to the first die 108(1), vertical interconnects 140 (e.g., metal pillars, metal posts, metal vertical interconnect accesses (vias), such as through-mold vias (TMVs)) are disposed in the package mold 132 of the first die package 110(1). The vertical interconnects 140 extend from a first bottom surface 142 of the interposer substrate 104 to a first top surface 144 of the package substrate 102 in the second, vertical direction (Z-axis direction) in this example. The vertical interconnects 140 are coupled to the metal interconnects 139 in the interposer substrate 104 adjacent the first bottom surface 142 of the interposer substrate 104. The vertical interconnects 140 are also coupled to the metal interconnects 120 in the first, upper metallization layers 112 of the package substrate 102 adjacent to the first top surface 144 of the package substrate 102. This provides signal routing paths between the second die 108(2) in the second die package 110(2), and the first die 108(1) and the external interconnects 126 through the package substrate 102.

Note that the IC package 100 in FIG. 1 could be just a single die package that includes the first die package 110(1) and does not include the second die package 110(2). In this option, the first die package 110(1) may not need to include the interposer substrate 104 and the vertical interconnects 140 to provide interconnections to the package substrate 102 for signal routing to the first die 108(1) and the external interconnects 126.

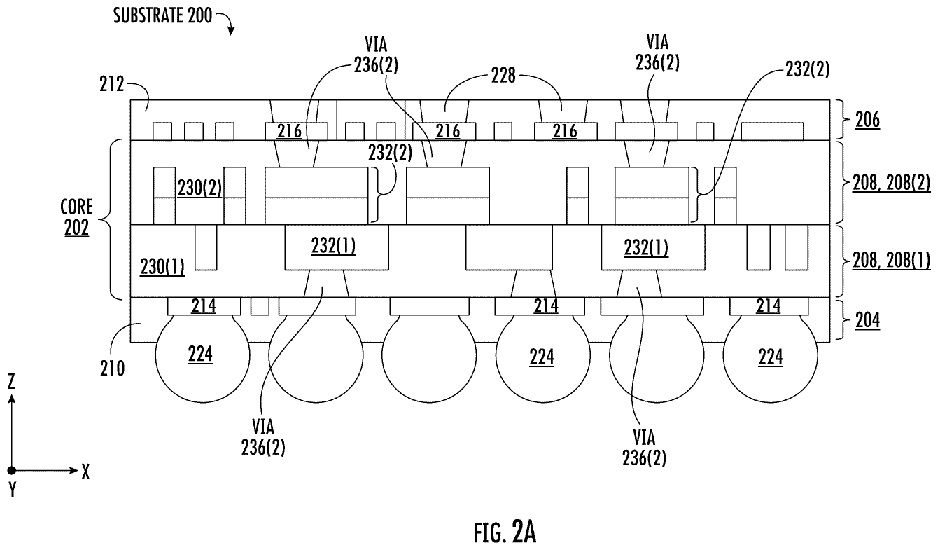

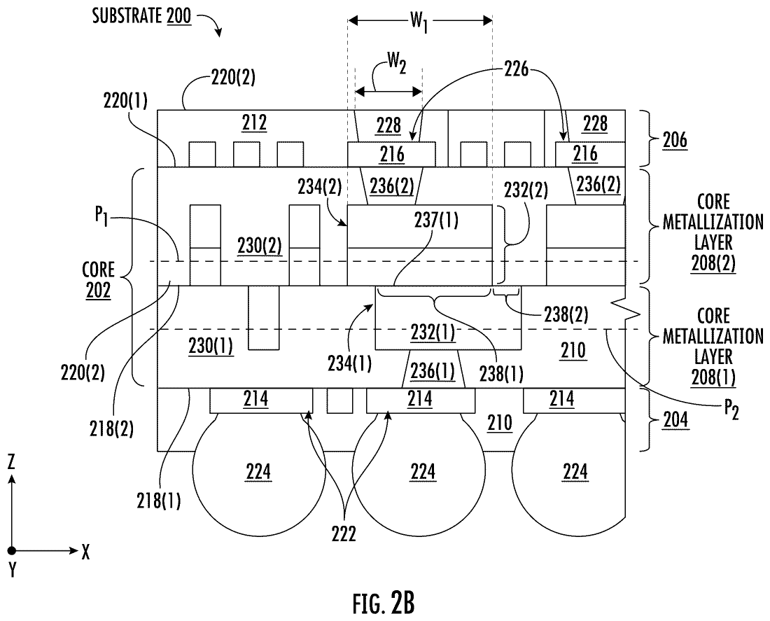

FIGS. 2A and 2B are a side view and close-up side view, respectively, of an exemplary package substrate 200 that can be included as the package substrate 102 and/or interposer substrate 104 in the IC package 100 in FIG. 1. The substrate 200 includes a core 202 surrounded in the second, vertical direction (Z-axis direction) by a first, outer and lower metallization layer 204 and a second, outer and upper metallization layer 206. The core 202 provides increased stiffness and rigidity for the substrate 200 and any IC package in which the substrate 200 is included. For example, as discussed above with regard to the IC package 100 example in FIG. 1, the core 202 can be made from a hardened, dielectric material (e.g., a PPG material) to provide increased stiffness and rigidity for the substrate 200, as opposed to using a less rigid dielectric material (e.g., epoxy-resin based materials and films (e.g. ABF) that may be used, for example, in the first, lower and second, upper metallization layers 204, 206. Each of the core 202, the first, lower metallization layer 204, and the second, upper metallization layer 206 extends in the first directions (X-axis and Y-axis directions). As discussed in more detail below, the core 202 includes multiple core metallization layers 208 each having metal interconnects coupled to each other to facilitate lateral signal routing in the first, lateral direction (X-axis and/or Y-axis direction) to provide increased signal routing flexibility in the substrate 200 and its first and second outer metallization layers 204, 206 and core 202.

As shown in FIGS. 2A and 2B, the core 202 of the substrate 200 includes a first, lower core metallization layer 208(1) adjacent to the first, lower metallization layer 204 in the second, vertical direction (Z-axis direction) in this example. The core 202 also includes a second, upper core metallization layer 208(2) adjacent to the second, upper metallization layer 206 in the second, vertical direction (Z-axis direction) in this example. The outer first and second metallization layers 204, 206 are solder resist layers in this example. The outer first and second metallization layers 204, 206 each include respective dielectric insulating layers 210, 212 that are made from a dielectric material with respective metal interconnects 214, 216 disposed therein. The insulating layers 210, 212 may be made from a material having a first rigidity, such as an epoxy-resin based material and film (e.g., ABF) that supports finer patterning capability for forming finer pitch metal interconnects therein with a reduced L/S ratio for increased signal routing density in the substrate 200. The first rigidity of the insulating layers 210, 210 is less than the rigidity of the core 202 in this example. In this example, as shown in FIG. 2B, the outer first and second metallization layers 204, 206 are semi-additive process (SAP) metallization layers where their respective metal interconnects 214, 216 are patterned and disposed on respective outer surfaces 218(1), 220(1) of the first and second core metallization layers 208(1), 208(2), with the insulating layers 210, 212 formed thereon to insulate the metal interconnects 214, 216. With regard to the first, lower metallization layer 204, openings 222 are formed in the insulating layer 210 to expose the metal interconnects 214 therein for coupling to external metal interconnects 224 (e.g., solder balls, BGA interconnects) for providing signal routing paths through the first, lower metallization layer 204 to the substrate 200. With regard to the second, upper metallization layer 206, openings 226 are formed in the insulating layer 212 to expose the metal interconnects 216 therein for coupling to respective vias 228 for providing signal routing paths to the second, upper metallization layer 206 and the substrate 200.

With reference to FIGS. 2A and 2B, the first and second core metallization layers 208(1), 208(2) of the core 202 each include respective first and second core insulating layers 230(1), 230(2) that are made from a dielectric material with the respective metal interconnects 214, 216 disposed therein. A “core insulating layer” is an insulating layer made from hardened, dielectric material (e.g., a PPG material) of rigidity greater than the first rigidity of traditional metallization layers used outside a core of a substrate to provide increased stiffness and rigidity from the core. In this regard, in this example, the first and second core insulating layers 230(1), 230(2) are made from a hardened, dielectric material (e.g., a PPG material) of a respective second and third rigidity greater than the first rigidity of the first, lower and second, upper metallization layers 204, 206, to provide increased stiffness and rigidity for the substrate 200. The first and second core insulating layers 230(1), 230(2) may be made from the same dielectric material with the same rigidity. In this example, as shown in FIGS. 2A and 2B, the first and second core metallization layers 208(1), 208(2) are ETS metallization layers where their respective first and second metal interconnects 232(1), 232(2) are patterned and embedded in the respective first and second core metallization layers 208(1), 208(2). One benefit of the core 202 including the first and second core metallization layers 208(1), 208(2) as ETS metallization layer is that ETS metallization layers can support a reduced L/S ratio to support finer pitched embedded first and second metal interconnects 232(1), 232(2) for increased routing density and capability in the core 202 of the substrate 200. For example, as shown in FIG. 2B, the first and second metal interconnects 232(1), 232(2) may be formed to have a first width W₁ as low as 85 micrometers (μm), and their coupled first and second vias 236(1), 236(2) have a second width W₂ as low as 55 μm.

During the fabrication of the core 202, as discussed in more detail below, openings 234(1), 234(2) are formed in the respective core insulating layers 230(1), 230(2) to expose the respective embedded first and second metal interconnects 232(1), 232(2) therein for forming the respective first and second vias 236(1), 236(2) in contact with the metal interconnects 232(1), 232(2). The first and second metal interconnects 232(1), 232(2) are coupled together by virtue of disposing the second core metallization layer 208(2) on the first core metallization layer 208(1) in the second, vertical direction (Z-axis direction) to provide signal routing paths between the between the first and second core metallization layers 208(1), 208(2) for signal routing within the core 202. In this example, to couple the first and second metal interconnects 232(1), 232(2) in the respective first and second core metallization layers 208(1) 208(2) together, the inner surfaces 218(2), 220(2) of the first and second core metallization layers 208(1) 208(2) are oriented in a back-to-back arrangement so that the exposed first and second metal interconnects 232(1), 232(2) from each inner first and second surface 218(2), 220(2) are adjacent to each other. This allows the first and second metal interconnects 232(1), 232(2) to be directly coupled to each other, if desired, to avoid the further need for metal pads to couple the first and second metal interconnects 232(1), 232(2) together, which may otherwise increase the height of the substrate 200 in the second, vertical direction (Z-axis direction) in an undesired manner. Note that in this example, as discussed in more detail below, the second core insulating layer 230(2) as part of the second core metallization layer 208(2) is formed on the first core insulating layer 230(2) of the first core metallization layer 208(1) before the second metal interconnects 232(2) are patterned and formed such that the first and second core insulating layers 230(1), 230(2) form a continuous insulating layer of dielectric material(s).

As further shown in FIG. 2B, the first and second vias 236(1), 236(2) are coupled to respective metal interconnects 214, 216 in the first and second outer metallization layers 204, 206. This provides signal routing paths between the first and second outer metallization layers 204, 206 and the core 202. For example, as shown in FIG. 2B, the first and second vias 236(1), 236(2) may be formed to have the width W₂ of 55 μm. By the core 202 including the first and second core metallization layers 208(1), 208(2), signal routing paths can be formed within the core 202 as opposed to only providing monolithic vertical interconnects that extend straight in the second, vertical direction (Z-axis direction) through the entire core 202 to couple the first and second outer metallization layers 204, 206. This also allows signal routing to be provided in the core 202 laterally in the first, horizontal direction(s) (X-axis and/or Y-axis directions) for signal routing flexibility. For example, as shown in FIG. 2B, the first and second metal interconnects 232(1), 232(2) in the respective first and second core metallization layers 208(1), 208(2) can be patterned to be extended in the first, horizontal direction(s) (X-axis and/or Y-axis directions) to extend signal routing paths laterally in the core 202.

The first and second metal interconnects 232(1), 232(2) in the respective first and second core metallization layers 208(1), 208(2) that are coupled to each other can be partially offset in the first, horizontal direction(s) (X-axis and/or Y-axis directions) (i.e., not fully aligned in the second, vertical direction (Z-axis direction)) to laterally shift the signal routing paths in the core 202 between the first and second core metallization layers 208(1), 208(2) in the second, vertical direction (Z-axis direction). For example, as shown in FIG. 2B, the first metal interconnects 232(1) may have a first surface 237(1) that does not fully overlap with a coupled second metal interconnect 232(2) in the second, vertical direction (Z-axis direction) to provide a laterally offset signal routing path between the first and second core metallization layers 208(1), 208(2) in the core 202. In this regard, the first metal interconnects 232(1) can have a first surface portion 238(1) of the first surface 237(1) that overlaps a coupled second metal interconnect 232(2) in the second, vertical direction (Z-axis direction) and a second surface portion 238(2) that does not overlap the coupled second metal interconnect 232(2) in the second, vertical direction (Z-axis direction). Said another way, a first metal interconnect 232(1) can extend in a first plane P₁ in the first, horizontal directions (X-axis and Y-axis directions), and a coupled second metal interconnect 232(2) can extend in a second plane P₂ in the first, horizontal directions (X-axis and Y-axis directions), wherein the first and second planes P₁, P₂ do not fully intersect each other in the second, vertical direction (Z-axis direction).

Similarly, as shown in FIG. 2B, by the core 202 including the first and second core metallization layers 208(1), 208(2), this allows signal routing paths within the core 202 to be routed laterally, in the first, horizontal direction(s), (X-axis and/or Y-axis direction(s)) to the first and second metallization layers 204, 206 to provide further enhanced signal routing flexibility in the core 202 and the substrate 200. In this regard, the core 202 including the first and second core metallization layers 208(1), 208(2) allows the formation of the respective first and second vias 236(1), 236(2) to be patterned laterally in the first, horizontal direction(s), (X-axis and/or Y-axis direction(s)) based on the patterned location of their coupled first and second metal interconnects 232(1), 232(2). In this manner, the locations of the first and second vias 236(1), 236(2) are not required to be completely aligned in the second, vertical direction (Z-axis), but instead can be at least partially offset or fully offset from each other in the first, horizontal direction(s), (X-axis and/or Y-axis direction(s)) to provide signal routing path flexibility within the core 202. In other words, the first and second vias 236(1), 236(2) do not have to be fully aligned in the second, vertical direction (Z-axis direction). This allows signal routing path flexibility in the outer, first and second metallization layers 204, 206, because the first and second vias 236(1), 236(2) have design freedom to be placed and shifted in location irrespective of the second and first vias 236(2), 236(1) in the second and first metallization layers 206, 204, as the signal routing paths are formed between the first and second core metallization layers 208(1), 208(2) of the core 202 and the outer, first and second metallization layers 204, 206.

FIG. 3 is a side view of another exemplary substrate 300 that includes the core 202 in the substrate 200 in FIGS. 2A and 2B, but is surrounded by multiple metallization layers 204, 204(2), 206(1)-206(3) on each outer surface 218(1), 220(1) of the respective core metallization layers 208(1), 208(2) of the core 202 in the second, vertical direction (Z-axis direction). The substrate 300 can also be used to provide the substrate 102 and/or substrate 104 in the IC package 100 in FIG. 1 as an example. Common element numbers are used for common components between the substrate 200 in FIGS. 2A and 2B and the substrate 300 in FIG. 3.

As shown in FIG. 3, one (1) additional first metallization layer 204(2) is provided in the substrate 300 between the outer, first metallization layer 204 and the core 202 to provide an additional first metallization layer below the core 202 for providing additional signal routing paths in the substrate 300. The additional first metallization layer 204(2) includes metal interconnects 214(2) that are coupled to the vias 236(1) of the first core metallization layer 208(1) and are also coupled to the metal interconnects 214 in the outer, first metallization layer 204 through vias 302(2). As also shown in FIG. 3, two (2) additional second metallization layers 206(2), 206(3) such that the second metallization layer 206(1) is between the second metallization layer 206(2) and the core 202 in the second, vertical direction (Z-axis direction) to provide additional metallization layers above the core 202 for providing additional signal routing paths in the substrate 300. The additional second metallization layers 206(2), 206(3) include respective metal interconnects 216(2), 216(3) that are coupled to the respective vias 236(2) of the second core metallization layer 208(2) and are also coupled to the metal interconnects 216 in the outer, second metallization layer 206(1) through respective vias 228(2), 228(3).

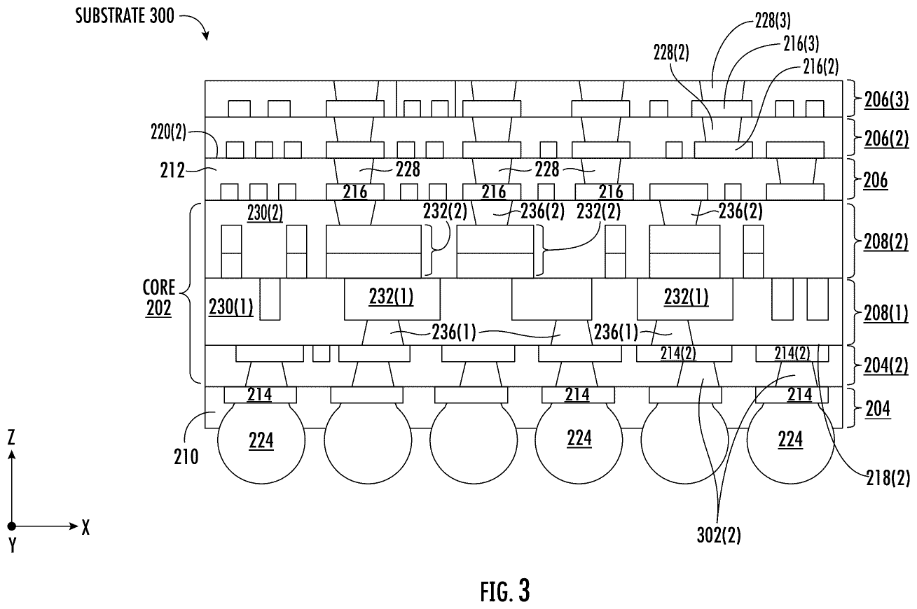

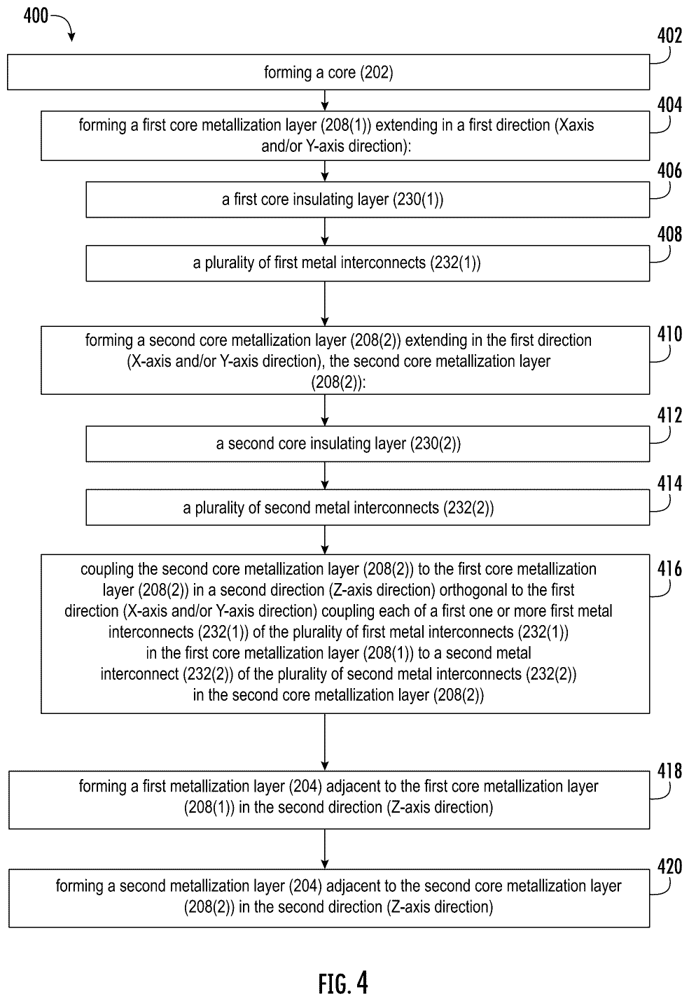

Package substrates that include a core surrounded by outer metallization layers in a second, vertical direction, wherein the core has multiple core metallization layers with metal interconnects in the respective core metallization layers coupled to each other to facilitate lateral signal routing in the first, lateral direction orthogonal to the second, vertical direction within the core, including, but not limited to, the substrates 102, 104, 200, 300 in FIGS. 1-3, can be fabricated according to a fabrication process. In this regard, FIG. 4 is a flowchart illustrating an exemplary fabrication process 400 of fabricating a package substrate that includes a core surrounded by outer metallization layers in a second, vertical direction, wherein the core has multiple core metallization layers with metal interconnects in the respective core metallization layers coupled to each other to facilitate lateral signal routing in the first, lateral direction orthogonal to the second, vertical direction within the core, including, but not limited to, the substrates 102, 104, 200, 300 in FIGS. 1-3. The process 400 in FIG. 4 is described with regard to the exemplary substrates 200, 300 in FIGS. 2A-3, but such is not limiting.

In this regard, as shown in FIG. 4, a first step of the fabrication process 400 can be forming the core 202 (block 402 in FIG. 4). Forming the core 202 can include forming a first core metallization layer 208(1) extending in a first direction (X-axis and/or Y-axis direction) (block 404 in FIG. 4), wherein the first core metallization layer 208(1) includes a first core insulating layer 230(1) (block 406 in FIG. 4), and a plurality of first metal interconnects 232(1) (block 408 in FIG. 4). Another step in the fabrication process of forming the core 202 can include forming a second core metallization layer 208(2) extending in the first direction (X-axis and/or Y-axis direction) (block 410 in FIG. 4), wherein the second core metallization layer 208(2) includes a second core insulating layer 230(2) (block 412 in FIG. 4) and a plurality of second metal interconnects 232(2) (block 414 in FIG. 4). Another step in the fabrication process 400 can include coupling the second core metallization layer 208(2) to the first core metallization layer 208(2) in a second direction (Z-axis direction) orthogonal to the first direction (X-axis and/or Y-axis direction) coupling each of a first one or more first metal interconnects 232(1) of the plurality of first metal interconnects 232(1) in the first core metallization layer 208(1) to a second metal interconnect 232(2) of the plurality of second metal interconnects 232(2) in the second core metallization layer 208(2) (block 416 in FIG. 4). Another step in the fabrication process 400 can include forming a first metallization layer 204 adjacent to the first core metallization layer 208(1) in the second direction (Z-axis direction) (block 418 in FIG. 4). Another step in the fabrication process 400 can include forming a second metallization layer 206 adjacent to the second core metallization layer 208(2) in the second direction (Z-axis direction) (block 420 in FIG. 4).

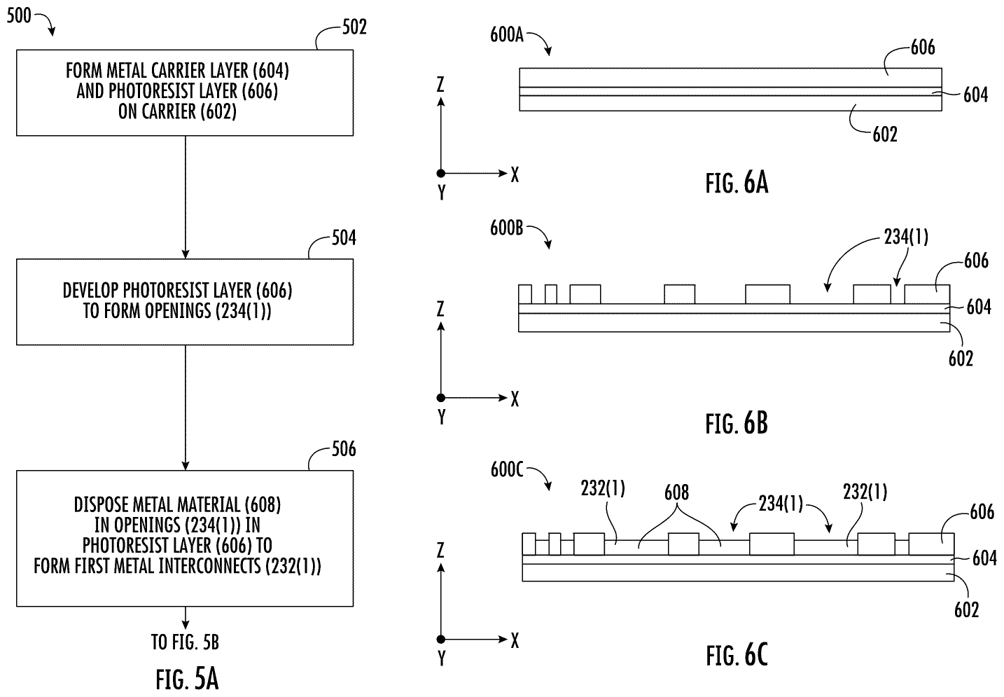

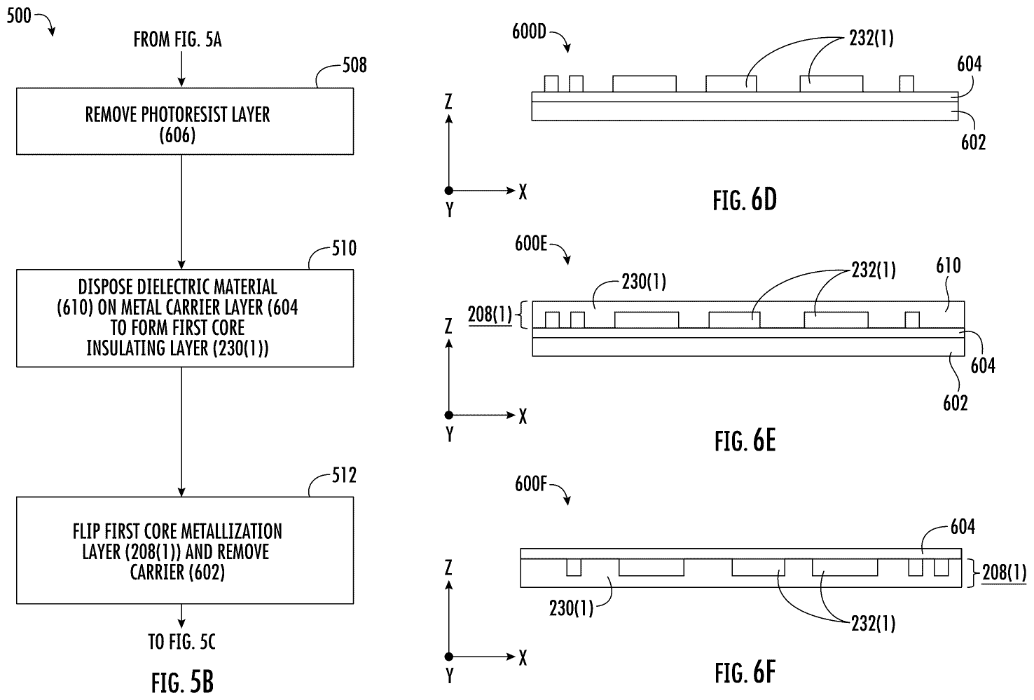

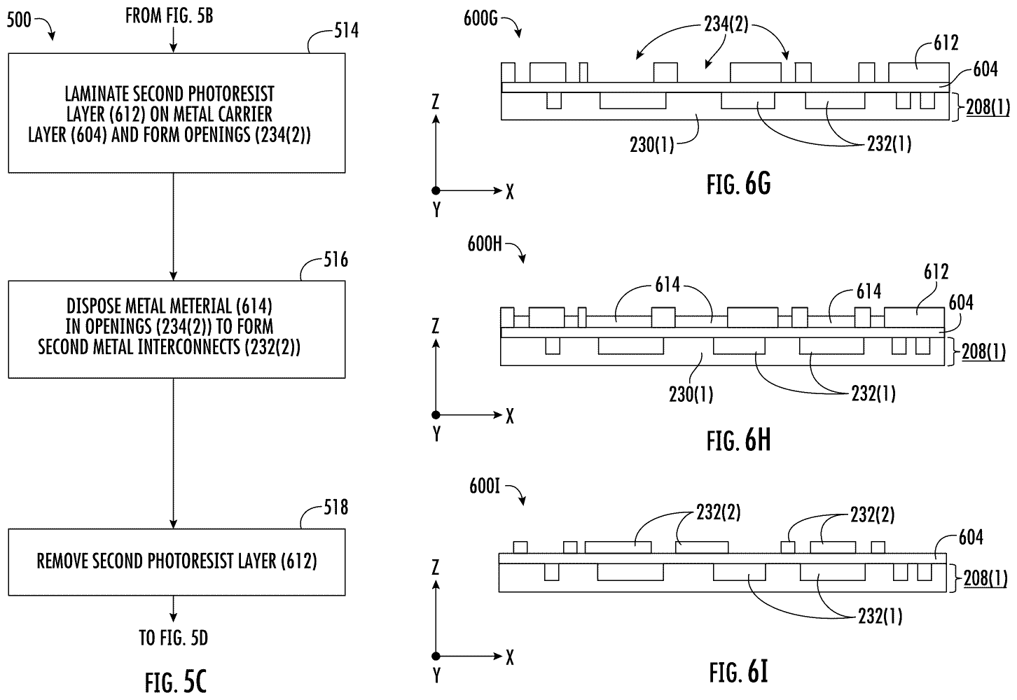

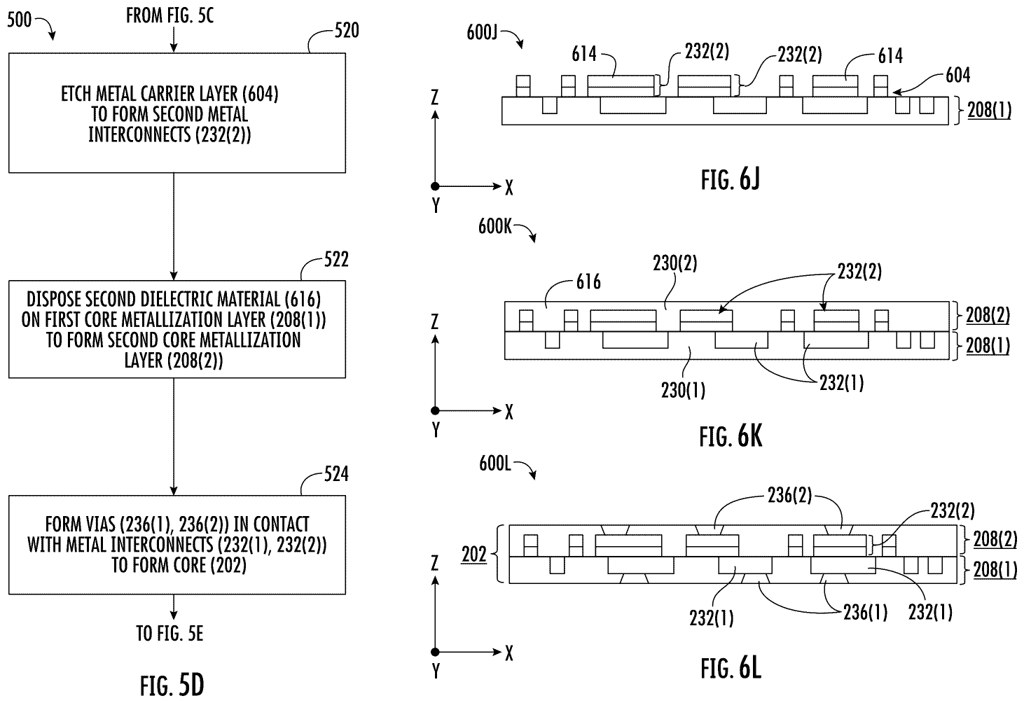

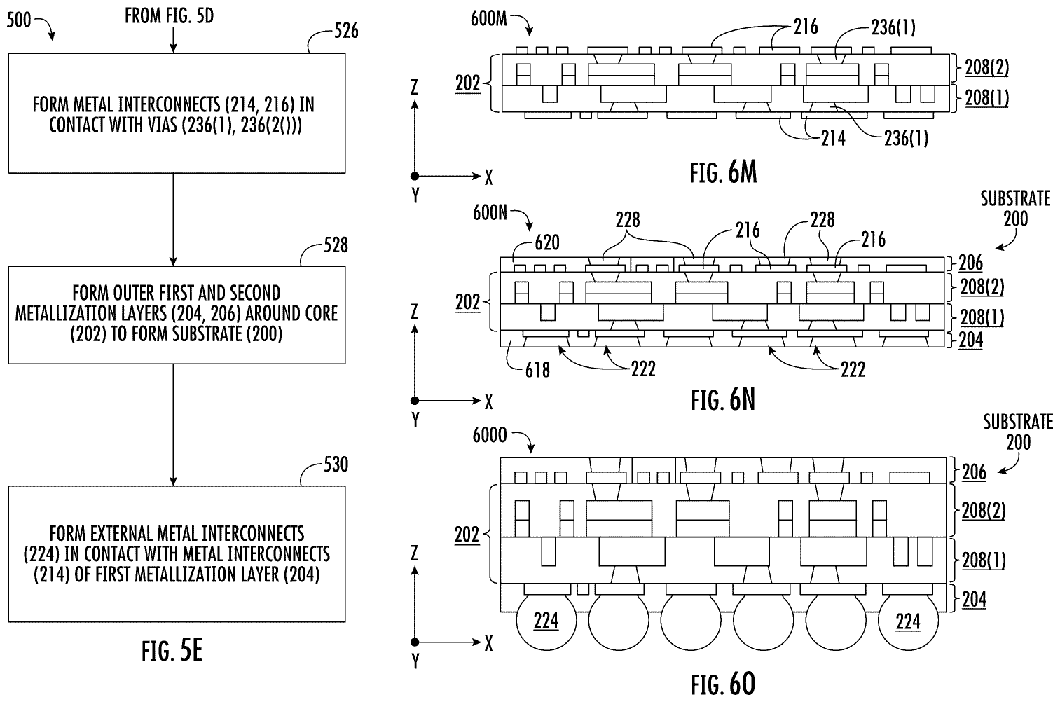

Package substrates that include a core surrounded by outer metallization layers in a second, vertical direction, wherein the core has multiple core metallization layers with metal interconnects in the respective core metallization layers coupled to each other to facilitate lateral signal routing in the first, lateral direction orthogonal to the second, vertical direction within the core, including, but not limited to, the substrates 102, 104, 200, 300 in FIGS. 1-3, can be fabricated according to other fabrication processes. For example, FIGS. 5A-5E is a flowchart illustrating a fabrication process 500 of fabricating a package substrate that includes a core surrounded by outer metallization layers in a second, vertical direction, wherein the core has multiple core ETS metallization layers with ETS metal interconnects in the respective core ETS metallization layers coupled to each other to facilitate lateral signal routing in the first, lateral direction orthogonal to the second, vertical direction within the core, including, but not limited to, the substrates 102, 104, 200, 300 in FIGS. 1-3. FIGS. 6A-6O are exemplary fabrication stages 600A-600O during fabrication of a substrate according to the exemplary fabrication process 500 in FIGS. 5A-5E. The fabrication process 500 in FIGS. 5A-5E is discussed below with reference to the exemplary substrate 200 in FIGS. 2A-2B, but such is not limiting and could be used to fabricate other substrates including the substrates 102, 104, 300 in FIGS. 1 and 3.

In this regard, as shown in the exemplary fabrication stage 600A in FIG. 6A, a first step in the fabrication process 500 of the substrate 200 can be to prepare the first core metallization layer 208(1) to be formed by lithography. The first core metallization layer 208(1) in this example will be an ETS metallization layer. This involves providing a resin carrier 602 and then plating a metal (e.g., copper) carrier layer 604 on the resin carrier 602 (block 502 in FIG. 5A). A photoresist layer 606 is laminated on the metal carrier layer 604, which can then be developed to form openings 234(1) for forming the embedded first metal interconnects 232(1). In this regard, as shown in fabrication stage 600B in FIG. 6B, the photoresist layer 606 is masked according to the pattern of the first metal interconnects 632(1) to be formed and is exposed to light (e.g., ultraviolet (UV) light) as part of a lithography process to form the openings 234(1) in the photoresist layer 606 for the first metal interconnects 232(1) to be formed (block 504 in FIG. 5A). Then, as shown in fabrication stage 600C in FIG. 6C, a next step in the fabrication process 500 is to fill the openings 234(1) in the photoresist layer 606 with a metal material 608 to form the first metal interconnects 232(1) (block 506 in FIG. 5A).

As shown in fabrication stage 600D in FIG. 6D, a next step in the fabrication process 500 is to remove the photoresist layer 606 such that the first metal interconnects 232(1) are fully exposed from the metal carrier layer 604 to prepare for insulating the first metal interconnects 232(1) (block 508 in FIG. 5B). Then, as shown in fabrication stage 600E in FIG. 6E, a next step in the fabrication process 500 is to dispose a dielectric material 610 on the metal carrier layer 604 and around the metal material 608 to form the first core insulating layer 230(1) of the first core metallization layer 208(1) (block 510 in FIG. 5B). Then, as shown in fabrication stage 600F in FIG. 6F, a next step in the fabrication process 500 is to flip the first core metallization layer 208(1) and to remove the resin carrier 602 to prepare for the second core metallization layer 208(2) to be formed as an ETS metallization layer on the first core metallization layer 208(1) to form the core 202 (block 512 in FIG. 5B).

Then, as shown in fabrication stage 600G in FIG. 6G, a next step in the fabrication process 500 to form the second core metallization layer 208(2) for the core 202 is to laminate a second photoresist layer 612 on the opposite side of the metal carrier layer 604 from the first core metallization layer 208(1), which is then developed to form openings 234(2) for forming the embedded second metal interconnects 232(2) (block 514 in FIG. 5C). Then, as shown in fabrication stage 600H in FIG. 6H, a next step in the fabrication process 500 is to fill the openings 234(2) in the second photoresist layer 612 with a metal material 614 to form the second metal interconnects 232(2) (block 516 in FIG. 5C). Then, as shown in fabrication stage 600I in FIG. 6I, a next step in the fabrication process 500 is remove the second photoresist layer 612 (block 518 in FIG. 5C).

Then, as shown in fabrication stage 600J in FIG. 6J, a next step in the fabrication process 500 is to etch through the openings formed between the metal material 614 forming the second metal interconnects 232(2) to remove portions of the metal carrier layer 604 outside of the metal material 614 using the metal material 614 as a mask (block 520 in FIG. 5D). This has the effect of making the portions of the metal carrier layer 604 that remain after etching coupled to the metal material 614 to form the second metal interconnects 232(2). In this manner, the metal carrier layer 604 is in essence reused to form part of the metal material for the second metal interconnects 232(2). Then, as shown in fabrication stage 600K in FIG. 6K, a next step in the fabrication process 500 is to dispose a second dielectric material 616 on the first core metallization layer 208(1) and around the second metal interconnects 232(2) exposed therefrom to form the second core insulating layer 230(2) of the second core metallization layer 208(2) (block 522 in FIG. 5D). Then, as shown in fabrication stage 600L in FIG. 6L, a next step in the fabrication process 500 is to form the first and second vias 236(1), 236(2) in the respective first and second core insulating layers 230(1), 230(2) in contact with the respective metal interconnects 232(1), 232(2) to form the core 202 (block 524 in FIG. 5D).

Then, a next step in the fabrication process 500 is to prepare the outer first and second metallization layers 204, 206 on each side of the core 202. In this regard, as shown in fabrication stage 600M in FIG. 6M, metal interconnects 214, 216 are patterned and formed in contact with the first and second vias 236(1), 236(2) exposed from their respective core insulating layers 230(1), 230(2) of the respective first and second core metallization layers 208(1), 208(2) (block 526 in FIG. 5E). Then, as shown in fabrication stage 600N in FIG. 6N, a next step in the fabrication process 500 is to form respective first and second insulating layers 618, 620 on the metal interconnects 214, 216 to form the respective outer, first and second metallization layers 204, 206 as solder resist layers in this example to form the substrate 200 (block 528 in FIG. 5E). Openings in the first and second insulating layers 618, 620 are formed to form the vias 228 in contact with the metal interconnects 216 in the second metallization layer 206, and the openings 222 in the first metallization layer 204 are formed to expose the metal interconnects 214 therein for coupling to external metal interconnects 224. Then, as shown in fabrication stage 600O in FIG. 6O, a next step in the fabrication process 500 is form the external metal interconnects 224 in contact with the metal interconnects 214 in the outer, first metallization layer 204 (block 530 in FIG. 5E).

It should be understood that the terms “first,” “second,” “third,” etc., where used herein, are relative terms and are not meant to limit or imply a strict orientation. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Package substrates that include a core surrounded by outer metallization layers in a second, vertical direction, wherein the core has multiple core metallization layers with metal interconnects in the respective core metallization layers coupled to each other to facilitate lateral signal routing in the first, lateral direction orthogonal to the second, vertical direction within the core, including but not limited to, the substrates 102, 104, 200, 300 in FIGS. 1-3, and that can be fabricated according to a fabrication process, including, but not limited to, the fabrication processes 400, 500 in FIGS. 4-5E, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

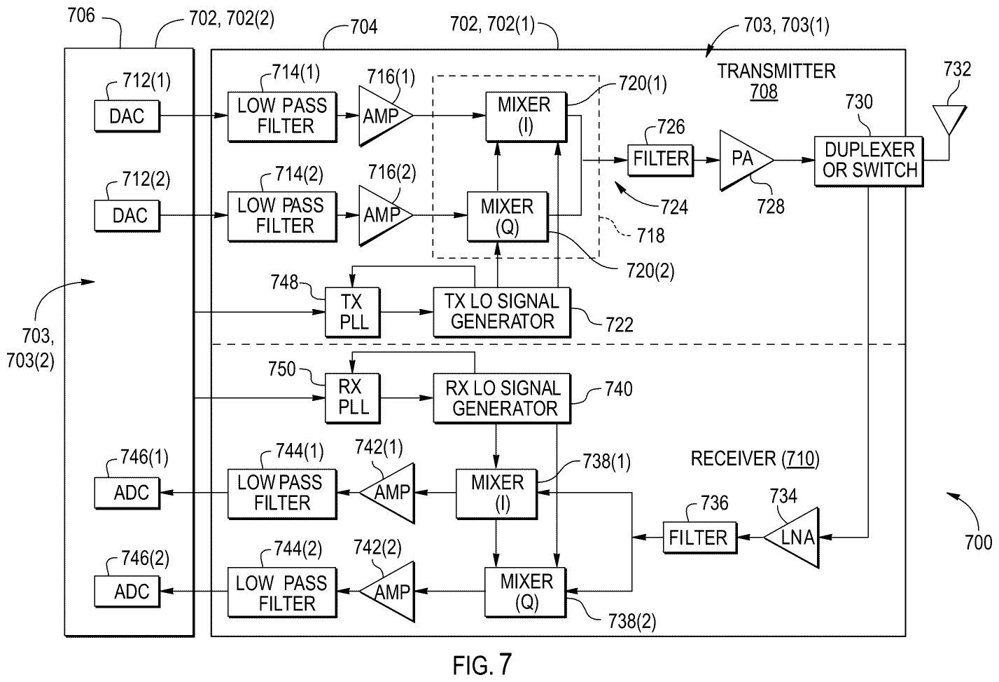

In this regard, FIG. 7 illustrates an exemplary wireless communications device 700 that includes one or more IC packages 702, 702(1), 702(2) that each include a substrate 703, 703(1), 703(2), including, but not limited to, the substrates 102, 104, 200, 300 in FIGS. 1-3 and 6O, that includes a core surrounded by outer metallization layers in a second, vertical direction, wherein the core has multiple core metallization layers with metal interconnects in the respective core metallization layers coupled to each other to facilitate lateral signal routing in the first, lateral direction orthogonal to the second, vertical direction within the core. The IC packages 702, 702(1), 702(2) and their substrates 703, 703(1), 703(2) can be fabricated according to a fabrication process, including, but not limited to, the exemplary fabrication processes 400, 500 in FIGS. 4-5E, and according to any aspects disclosed herein.

The wireless communications device 700 may include or be provided in any of the above-referenced devices, as examples. As shown in FIG. 7, the wireless communications device 700 includes a transceiver 704 and a data processor 706. The data processor 706 may include a memory to store data and program codes. The transceiver 704 includes a transmitter 708 and a receiver 710 that support bi-directional communications. In general, the wireless communications device 700 may include any number of transmitters 708 and/or receivers 710 for any number of communication systems and frequency bands. All or a portion of the transceiver 704 may be implemented on one or more analog ICs, RF ICs (RFICs), mixed-signal ICs, etc.

The transmitter 708 or the receiver 710 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 710. In the direct-conversion architecture, a signal is frequency-converted between RF and baseband in one stage. The super-heterodyne and direct-conversion architectures may use different circuit blocks and/or have different requirements. In the wireless communications device 700 in FIG. 7, the transmitter 708 and the receiver 710 are implemented with the direct-conversion architecture.

In the transmit path, the data processor 706 processes data to be transmitted and provides I and Q analog output signals to the transmitter 708. In the exemplary wireless communications device 700, the data processor 706 includes digital-to-analog converters (DACs) 712(1), 712(2) for converting digital signals generated by the data processor 706 into the I and Q analog output signals, e.g., I and Q output currents, for further processing.

Within the transmitter 708, lowpass filters 714(1), 714(2) filter the I and Q analog output signals, respectively, to remove undesired signals caused by the prior digital-to-analog conversion. Amplifiers (AMPs) 716(1), 716(2) amplify the signals from the lowpass filters 714(1), 714(2), respectively, and provide I and Q baseband signals. An upconverter 718 upconverts the I and Q baseband signals with I and Q transmit (TX) local oscillator (LO) signals through mixers 720(1), 720(2) from a TX LO signal generator 722 to provide an upconverted signal 724. A filter 726 filters the upconverted signal 724 to remove undesired signals caused by the frequency upconversion as well as noise in a receive frequency band. A power amplifier (PA) 728 amplifies the upconverted signal 724 from the filter 726 to obtain the desired output power level and provides a transmit RF signal. The transmit RF signal is routed through a duplexer or switch 730 and transmitted via an antenna 732.

In the receive path, the antenna 732 receives signals transmitted by base stations and provides a received RF signal, which is routed through the duplexer or switch 730 and provided to a low noise amplifier (LNA) 734. The duplexer or switch 730 is designed to operate with a specific receive (RX)-to-TX duplexer frequency separation, such that RX signals are isolated from TX signals. The received RF signal is amplified by the LNA 734 and filtered by a filter 736 to obtain a desired RF input signal. Downconversion mixers 738(1), 738(2) mix the output of the filter 736 with I and Q RX LO signals (i.e., LO_I and LO_Q) from an RX LO signal generator 740 to generate I and Q baseband signals. The I and Q baseband signals are amplified by AMPs 742(1), 742(2) and further filtered by lowpass filters 744(1), 744(2) to obtain I and Q analog input signals, which are provided to the data processor 706. In this example, the data processor 706 includes analog-to-digital converters (ADCs) 746(1), 746(2) for converting the analog input signals into digital signals to be further processed by the data processor 706.

In the wireless communications device 700 of FIG. 7, the TX LO signal generator 722 generates the I and Q TX LO signals used for frequency upconversion, while the RX LO signal generator 740 generates the I and Q RX LO signals used for frequency downconversion. Each LO signal is a periodic signal with a particular fundamental frequency. A TX phase-locked loop (PLL) circuit 748 receives timing information from the data processor 706 and generates a control signal used to adjust the frequency and/or phase of the TX LO signals from the TX LO signal generator 722. Similarly, an RX PLL circuit 750 receives timing information from the data processor 706 and generates a control signal used to adjust the frequency and/or phase of the RX LO signals from the RX LO signal generator 740.

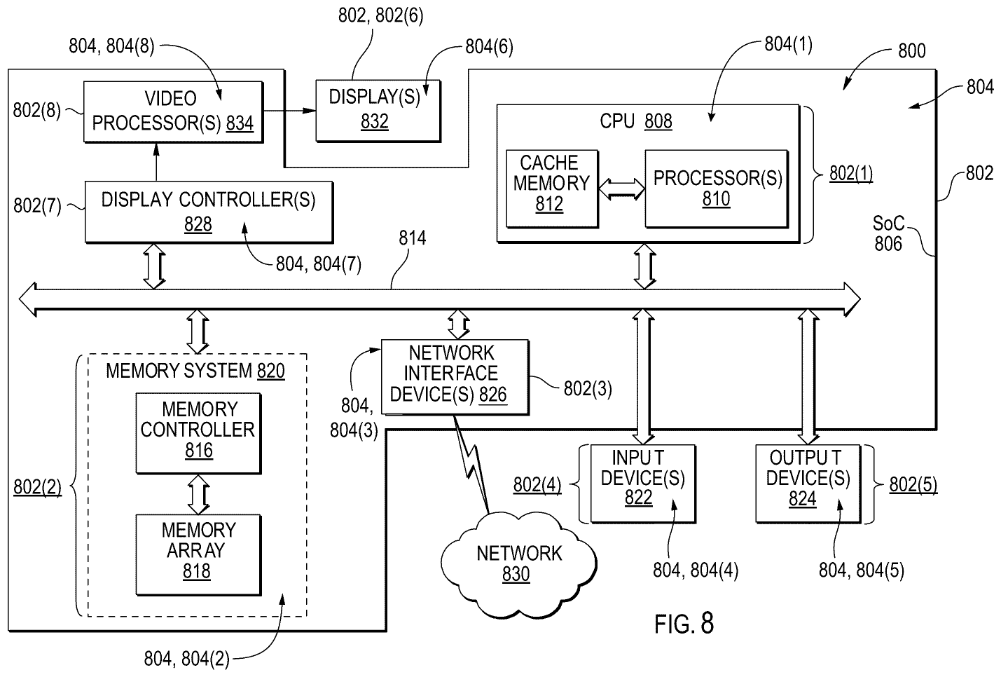

FIG. 8 illustrates an example of a processor-based system 800 that includes one or more IC packages 802, 802(1)-802(8) that each include a substrate 804, 804(1)-804(8), including, but not limited to, the substrates 102, 104, 200, 300 in FIGS. 1-3 and 6O, that includes a core surrounded by outer metallization layers in a second, vertical direction, wherein the core has multiple core metallization layers with metal interconnects in the respective core metallization layers coupled to each other to facilitate lateral signal routing in the first, lateral direction orthogonal to the second, vertical direction within the core. The IC packages 802, 802(1)-802(8) and their substrates 804, 804(1)-804(8) can be fabricated according to a fabrication process, including, but not limited to, the exemplary fabrication processes 400, 500 in FIGS. 4-5E, and according to any aspects disclosed herein.

In this example, the processor-based system 800 may include a substrate 804 that is included in an IC package 802, such as a system-on-a-chip (SoC) 806. The processor-based system 800 includes a CPU 808 that includes one or more processors 810, which may also be referred to as CPU cores or processor cores. The CPU 808 can be provided in an IC package 802(1) that includes the substrate 804(1). The CPU 808 may have cache memory 812 coupled to the CPU 808 for rapid access to temporarily stored data. The CPU 808 is coupled to a system bus 814 and can intercouple master and slave devices included in the processor-based system 800. As is well known, the CPU 808 communicates with these other devices by exchanging address, control, and data information over the system bus 814. For example, the CPU 808 can communicate bus transaction requests to a memory controller 816 as an example of a slave device. Although not illustrated in FIG. 8, multiple system buses 814 could be provided, wherein each system bus 814 constitutes a different fabric.

Other master and slave devices can be connected to the system bus 814. As illustrated in FIG. 8, these devices can include a memory system 820 that includes the memory controller 816 and a memory array(s) 818, one or more input devices 822, one or more output devices 824, one or more network interface devices 826, and one or more display controllers 828, as examples. The memory system 820 can be provided in an IC package 802(2) that includes the substrate 804(2). The network interface devices 826 can be provided in an IC package 802(3) that includes the substrate 804(3). Each of the memory system 820, the one or more input devices 822, the one or more output devices 824, the one or more network interface devices 826, and the one or more display controllers 828 can be provided in the same or different circuit packages. The input devices 822 and/or the output devices 824 can be provided in a respective IC package 802(4), 802(5) that includes a respective substrate 804(4), 804(5). The input device(s) 822 can include any type of input device, including, but not limited to, input keys, switches, voice processors, etc. The output device(s) 824 can include any type of output device, including, but not limited to, audio, video, other visual indicators, etc. The network interface device(s) 826 can be any device configured to allow exchange of data to and from a network 830. The network 830 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 826 can be configured to support any type of communications protocol desired.

The CPU 808 may also be configured to access the display controller(s) 828 over the system bus 814 to control information sent to one or more displays 832. The display(s) 832 can be provided in an IC package 802(6) that includes the substrate 804(6). The display controller(s) 828 sends information to the display(s) 832 to be displayed via one or more video processors 834, which process the information to be displayed into a format suitable for the display(s) 832. The display controller(s) 828 and video processor(s) 834 can be provided in a respective IC package 802(7), 802(8) that includes the substrate 804(7), 804(8), or be provided in the same IC package 802, or be provided in the same IC package 802(1) containing the CPU 808 as an example. The display(s) 832 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A substrate, comprising:
a first metallization layer extending in a first direction;
a second metallization layer extending in the first direction; and
a core between the first metallization layer and the second metallization layer in a second direction orthogonal to the first direction,
the core, comprising:
   a first core metallization layer, comprising:
      a first core insulating layer; and
      a plurality of first metal interconnects; and
   a second core metallization layer adjacent to the first core metallization layer in the second direction, the second core metallization layer comprising:
      a second core insulating layer; and
      a plurality of second metal interconnects,
   a first one or more first metal interconnects of the plurality of first metal interconnects in the first core metallization layer each coupled to a second metal interconnect of the plurality of second metal interconnects in the second core metallization layer.

2. The substrate of clause 1, wherein a second one or more first metal interconnects of the plurality of first metal interconnects in the first core metallization layer are each coupled to a third, first metal interconnect of the plurality of first metal interconnects in the first core metallization layer.

3. The substrate of clause 1 or 2, wherein each of the first one or more first metal interconnects is at least partially offset from a coupled second metal interconnect of the plurality of second metal interconnects in the first direction.

4. The substrate of any of clauses 1-3, wherein each of the first one or more first metal interconnects comprises a first surface comprising a first surface portion in contact with its coupled second metal interconnect and a second surface portion not coupled to its coupled second metal interconnect.

5. The substrate of any of clauses 1-4, wherein:
the plurality of first metal interconnects extends in a first plane in the first direction;
the plurality of second metal interconnects extends in a second plane in the first direction; and
the first plane only partially intersects the second plane in the second direction.

6. The substrate of any of clauses 1-5, wherein:
the first core metallization layer further comprises one or more first vias in the first core insulating layer, the one or more first vias each coupled to a first metal interconnect of the first one or more first metal interconnects; and
the second core metallization layer further comprises one or more second vias in the second core insulating layer, the one or more second vias each coupled to a second metal interconnect of the plurality of second metal interconnects.

7. The substrate of clause 6, wherein a first via of the one or more first vias coupled to the first metal interconnect is at least partially offset in the first direction from a second via of the one or more second vias coupled to the second metal interconnect.

8. The substrate of clause 6 or 7, wherein the first via is not fully aligned to the second via in the second direction.

9. The substrate of clause 7 or 8, wherein:
the first via is coupled to a third metal interconnect in the first metallization layer adjacent to the first core metallization layer; and
the second via is coupled to a fourth metal interconnect in the second metallization layer adjacent to the second core metallization layer.

10. The substrate of any of clauses 1-9, wherein:
the first metallization layer comprises a first insulating layer comprising a first dielectric material having a first rigidity;
the first core insulating layer comprises a second dielectric material having a second rigidity greater than the first rigidity of the first dielectric material; and
the second core insulating layer comprises a third dielectric material having a third rigidity greater than the first rigidity of the first dielectric material.

11. The substrate of clause 10, wherein the second metallization layer comprises a second insulating layer comprising the first dielectric material having the first rigidity.

12. The substrate of any of clauses 1-11, wherein:
the first core insulating layer comprises a first surface adjacent to the first metallization layer and a second surface opposite the first surface in the second direction;
the plurality of first metal interconnects is adjacent to the second surface of the first core insulating layer;
the second core insulating layer comprises a third surface and a fourth surface opposite the third surface in the second direction and adjacent to the second metallization layer; and
the plurality of second metal interconnects is adjacent to the third surface of the second core insulating layer.

13. The substrate of any of clauses 1-12, wherein:
the first core metallization layer comprises a first core embedded trace substrate (ETS) metallization layer comprising the plurality of first metal interconnects embedded in the first core insulating layer; and
the second core metallization layer comprises a second core ETS metallization layer comprising the plurality of second metal interconnects embedded in the second core insulating layer.

14. The substrate of any of clauses 1-13, wherein the first core insulating layer and the second core insulating layer form a continuous insulating layer of a first dielectric material.

15. The substrate of any of clauses 6-9, wherein:
a first metal interconnect of the first one or more first metal interconnects has a first width in the first direction of 85 micrometers (μm); and
a first via of the one or more first vias coupled to the first metal interconnect has a second width of 55 μm.

16. The substrate of any of clauses 1-15, further comprising:
a third metallization layer coupled to the first metallization layer, such that the first metallization layer is between the core and the third metallization layer in the second direction; and
a fourth metallization layer coupled to the second metallization layer, such that the second metallization layer is between the core and the fourth metallization layer in the second direction.

17. The substrate of any of clauses 1-16 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

18. A method of fabricating a substrate for an integrated circuit (IC) package, comprising:
forming a core, comprising:
   forming a first core metallization layer extending in a first direction, comprising:
      forming a first core insulating layer; and
      forming a plurality of first metal interconnects; and
   forming a second core metallization layer extending in the first direction, comprising:
      forming a second core insulating layer; and
      forming a plurality of second metal interconnects; and
   coupling the second core metallization layer to the first core metallization layer in a second direction orthogonal to the first direction coupling each of a first one or more first metal interconnects of the plurality of first metal interconnects in the first core metallization layer to a second metal interconnect of the plurality of second metal interconnects in the second core metallization layer;
forming a first metallization layer adjacent to the first core metallization layer in the second direction; and
forming a second metallization layer adjacent to the second core metallization layer in the second direction.

19. The method of clause 18, coupling each of the first one or more first metal interconnects of the plurality of first metal interconnects in the first core metallization layer to the second metal interconnect of the plurality of second metal interconnects in the second core metallization layer further comprises:
coupling a first metal interconnects of the first one or more first metal interconnects layer is at least partially offset to a second metal interconnect of the plurality of second metal interconnects in the first direction.

20. The method of clause 18 or 19, wherein:
forming the first core metallization layer further comprises forming one or more first vias in the first core insulating layer each coupled to a first metal interconnect of the first one or more first metal interconnects; and
forming the second core metallization layer further comprises forming one or more second vias in the second core insulating layer, the one or more second vias each coupled to a second metal interconnect of the plurality of second metal interconnects.

21. The method of clause 20, wherein a first via of the one or more first vias coupled to the first metal interconnect is at least partially offset in the first direction from a second via of the one or more second vias coupled to the second metal interconnect.

22. The method of any of clauses 18-21, wherein:
forming the first core metallization layer comprises forming a first core embedded trace substrate (ETS) metallization layer comprising:
   forming the first core insulating layer; and
   embedding the plurality of first metal interconnects in the first core insulating layer; and
forming the second core metallization layer comprises forming a first second ETS metallization layer comprising:
   forming the second core insulating layer; and
   embedding the plurality of second metal interconnects in the second core insulating layer.

23. The method of any of clauses 18-22, wherein:
forming the first core metallization layer comprises:
   forming a metal carrier layer;
   forming the plurality of first metal interconnects on a first side of the metal carrier layer and in contact with the metal carrier layer; and
   forming the first core insulating layer on the first side of the metal carrier layer and the plurality of first metal interconnects; and
forming the second core metallization layer comprises:
   forming the plurality of metal material on a second side of the metal carrier layer opposite the first side and in contact with the metal carrier layer; and
   etching the metal carrier layer outside the plurality of metal material to form the plurality of second metal interconnects
   forming the second core insulating layer on the plurality of second metal interconnects.

What is claimed is:

1. A substrate, comprising:
a first metallization layer extending in a first direction;
a second metallization layer extending in the first direction; and
a core between the first metallization layer and the second metallization layer in a second direction orthogonal to the first direction,
the core, comprising:
a first core metallization layer, comprising:
a first core insulating layer; and
a plurality of first metal interconnects; and
a second core metallization layer adjacent to the first core metallization layer in the second direction, the second core metallization layer comprising:
a second core insulating layer; and
a plurality of second metal interconnects,
a first one or more first metal interconnects of the plurality of first metal interconnects in the first core metallization layer each coupled to a second metal interconnect of the plurality of second metal interconnects in the second core metallization layer.

2. The substrate of claim 1, wherein a second one or more first metal interconnects of the plurality of first metal interconnects in the first core metallization layer are each coupled to a third, first metal interconnect of the plurality of first metal interconnects in the first core metallization layer.

3. The substrate of claim 1, wherein each of the first one or more first metal interconnects is at least partially offset from a coupled second metal interconnect of the plurality of second metal interconnects in the first direction.

4. The substrate of claim 1, wherein each of the first one or more first metal interconnects comprises a first surface comprising a first surface portion in contact with its coupled second metal interconnect and a second surface portion not coupled to its coupled second metal interconnect.

5. The substrate of claim 1, wherein:
the plurality of first metal interconnects extends in a first plane in the first direction;
the plurality of second metal interconnects extends in a second plane in the first direction; and
the first plane only partially intersects the second plane in the second direction.

6. The substrate of claim 1, wherein:
the first core metallization layer further comprises one or more first vias in the first core insulating layer, the one or more first vias each coupled to a first metal interconnect of the first one or more first metal interconnects; and
the second core metallization layer further comprises one or more second vias in the second core insulating layer, the one or more second vias each coupled to a second metal interconnect of the plurality of second metal interconnects.

7. The substrate of claim 6, wherein a first via of the one or more first vias coupled to the first metal interconnect is at least partially offset in the first direction from a second via of the one or more second vias coupled to the second metal interconnect.

8. The substrate of claim 6, wherein the first via is not fully aligned to the second via in the second direction.

9. The substrate of claim 7, wherein:
the first via is coupled to a third metal interconnect in the first metallization layer adjacent to the first core metallization layer; and
the second via is coupled to a fourth metal interconnect in the second metallization layer adjacent to the second core metallization layer.

10. The substrate of claim 1, wherein:
the first metallization layer comprises a first insulating layer comprising a first dielectric material having a first rigidity;
the first core insulating layer comprises a second dielectric material having a second rigidity greater than the first rigidity of the first dielectric material; and
the second core insulating layer comprises a third dielectric material having a third rigidity greater than the first rigidity of the first dielectric material.

11. The substrate of claim 10, wherein the second metallization layer comprises a second insulating layer comprising the first dielectric material having the first rigidity.

12. The substrate of claim 1, wherein:
the first core insulating layer comprises a first surface adjacent to the first metallization layer and a second surface opposite the first surface in the second direction;
the plurality of first metal interconnects is adjacent to the second surface of the first core insulating layer;
the second core insulating layer comprises a third surface and a fourth surface opposite the third surface in the second direction and adjacent to the second metallization layer; and
the plurality of second metal interconnects is adjacent to the third surface of the second core insulating layer.

13. The substrate of claim 1, wherein:
the first core metallization layer comprises a first core embedded trace substrate (ETS) metallization layer comprising the plurality of first metal interconnects embedded in the first core insulating layer; and
the second core metallization layer comprises a second core ETS metallization layer comprising the plurality of second metal interconnects embedded in the second core insulating layer.

14. The substrate of claim 1, wherein the first core insulating layer and the second core insulating layer form a continuous insulating layer of a first dielectric material.

15. The substrate of claim 6, wherein:
a first metal interconnect of the first one or more first metal interconnects has a first width in the first direction of 85 micrometers (μm); and
a first via of the one or more first vias coupled to the first metal interconnect has a second width of 55 μm.

16. The substrate of claim 1, further comprising:
a third metallization layer coupled to the first metallization layer, such that the first metallization layer is between the core and the third metallization layer in the second direction; and
a fourth metallization layer coupled to the second metallization layer, such that the second metallization layer is between the core and the fourth metallization layer in the second direction.

17. The substrate of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

18. A method of fabricating a substrate for an integrated circuit (IC) package, comprising:
forming a core, comprising:
forming a first core metallization layer extending in a first direction, comprising:
forming a first core insulating layer; and
forming a plurality of first metal interconnects; and
forming a second core metallization layer extending in the first direction, comprising:
forming a second core insulating layer; and
forming a plurality of second metal interconnects; and
coupling the second core metallization layer to the first core metallization layer in a second direction orthogonal to the first direction coupling each of a first one or more first metal interconnects of the plurality of first metal interconnects in the first core metallization layer to a second metal interconnect of the plurality of second metal interconnects in the second core metallization layer;
forming a first metallization layer adjacent to the first core metallization layer in the second direction; and
forming a second metallization layer adjacent to the second core metallization layer in the second direction.

19. The method of claim 18, coupling each of the first one or more first metal interconnects of the plurality of first metal interconnects in the first core metallization layer to the second metal interconnect of the plurality of second metal interconnects in the second core metallization layer further comprises:
coupling a first metal interconnects of the first one or more first metal interconnects layer is at least partially offset to a second metal interconnect of the plurality of second metal interconnects in the first direction.

20. The method of claim 18, wherein:
forming the first core metallization layer further comprises forming one or more first vias in the first core insulating layer each coupled to a first metal interconnect of the first one or more first metal interconnects; and
forming the second core metallization layer further comprises forming one or more second vias in the second core insulating layer, the one or more second vias each coupled to a second metal interconnect of the plurality of second metal interconnects.

21. The method of claim 20, wherein a first via of the one or more first vias coupled to the first metal interconnect is at least partially offset in the first direction from a second via of the one or more second vias coupled to the second metal interconnect.

22. The method of claim 18, wherein:
forming the first core metallization layer comprises forming a first core embedded trace substrate (ETS) metallization layer comprising:
forming the first core insulating layer; and
embedding the plurality of first metal interconnects in the first core insulating layer; and
forming the second core metallization layer comprises forming a first second ETS metallization layer comprising:
forming the second core insulating layer; and
embedding the plurality of second metal interconnects in the second core insulating layer.

23. The method of claim 18, wherein:
forming the first core metallization layer comprises:
forming a metal carrier layer;
forming the plurality of first metal interconnects on a first side of the metal carrier layer and in contact with the metal carrier layer; and
forming the first core insulating layer on the first side of the metal carrier layer and the plurality of first metal interconnects; and
forming the second core metallization layer comprises:
forming the plurality of metal material on a second side of the metal carrier layer opposite the first side and in contact with the metal carrier layer, and
etching the metal carrier layer outside the plurality of metal material to form the plurality of second metal interconnects
forming the second core insulating layer on the plurality of second metal interconnects.
